(19) United States
(12) Patent Application Publication
(10) Pub. No.: US 2007/0052079 A1
(43) Pub. Date: Mar. 8, 2007

(54) Multi-chip stacking package structure

(75) Inventors: Chen-Jung Tsai, Hsin-chu (TW); Chih-Wen Lin, Hsin-chu (TW)

Correspondence Address: FINNEGAN, HENDERSON, FARABOW, GARRETT & DUNNER;LLP, 901 NEW YORK AVENUE, NW, WASHINGTON, DC, 20001-4413, US

(73) Assignee: Macronix International Co., Ltd.

(21) Appl. No.: 11/219,815

(22) Filed: Sep. 7, 2005

(51) Int. Cl. H01L 23/02

(52) U.S. Cl. 257/685

(57) ABSTRACT

A multi-chip stacked package structure, including a leadframe base thin package structure with two or more chips in the stacking structure, is provided that is capable of including two or more stacked chips that reduce the total stacking thickness. The package structure also reduces stacking thickness by achieving stacking of four or more chips into the area of a thin small outline package structure.

### TECHNICAL FIELD

The present invention generally relates to a multi-chip stacking package structure. More particularly, this invention relates to a multi-chip stacked package structure that is capable of providing two or more stacked chips while reducing a total stacking thickness, thereby increasing chip package density and integration.

### DESCRIPTION OF THE RELATED ART

As demand continues to increase for electronic devices that are smaller with increased functionality, there is also increasing demand for semiconductor packages that have smaller outlines and mounting footprints, yet which are capable of increased component packaging densities. One approach to satisfying this demand has been the development of techniques for stacking the semiconductor dies, or “chips,” contained in the package on top of one another.

Multi-chip packaging technology is used to pack two or more semiconductor dies in a single package unit, so that the single package unit is capable of offering increased functionality or data storage capacity. For example, memory chips, such as flash memory chips, are packaged in this way to allow a single memory module to offer an increased data storage capacity.

In order to connect a given semiconductor die with other circuitry, the die is (using conventional packaging technology) mounted on a lead frame paddle of a lead-frame strip which consists of a series of interconnected lead frames, for example, ten in a row. The die-mounting paddle of a standard lead frame is larger than the die itself, and it is surrounded by multiple lead fingers of individual leads. The bonding pads of the die are then connected one by one in a wire-bonding operation to the lead frame lead finger pads with fine gold or aluminum wire. Following the application of a protective layer to the face of the die, the die and a portion of the lead frame to which it is attached are encapsulated in a plastic/resin material, as are all other die/lead-frame assemblies on the lead-frame strip. A trim-and-form operation then separates the resultant interconnected packages and bends the leads of each package into a desired configuration.

A common problem experienced with packages containing multiple dies, and particularly in lead frame types of packages, is the limited availability of internal electrical interconnections and signal routings possible between the dies themselves, and between the dies and the input/output terminals of the package. In the case of lead frame packages, these terminals consist of the leads of the lead frame, which may be relatively few in comparison with the number of wire bonding pads on the dies. Thus, the packaging of multiple dies in a lead frame package format has typically been limited to a simple “fan-out” interconnection of the dies to the leads, with very limited die-to-die interconnection and signal routing capability. Multiple-die packages requiring a more complex die-to-die interconnection and routing capabilities have been implemented in relatively more expensive, laminate-based packages, e.g., ball grid array (“BGA”) packages.

Another common problem experienced with packages containing multiple dies, and particularly in leadframe types of packages, is the limited area available for die mounting and the overall height of the package. Therefore, there is a need to provide a multi-chip stacked package structure that is capable of providing two or more stacked chips while reducing the total stacking thickness, thereby increasing chip package density and integration.

The present invention is directed to overcome one or more of the problems of the related art.

### SUMMARY OF THE INVENTION

In accordance with the purpose of the invention as embodied and broadly described, there is provided a multi-chip stacked packaging structure, comprising at least one first chip, having a first active surface and a first back surface, the first active surface comprising a central area and a peripheral area having a plurality of first bonding pads; a lead frame, comprising a plurality of leads and a chip supporting pad having at least a first adhering surface and a second adhering surface, the first adhering surface adhered to the first active surface to leave exposed the first bonding pads; at least one second chip, having a second active surface and a second back surface, the second active surface comprising a central area and a peripheral area having a plurality of second bonding pads, the second active surface adhered to the second adhering surface of the lead frame to leave exposed the second bonding pads; and a plurality of wires, wherein parts of the wires electrically interconnect the first bonding pads and at least some of the leads, and parts of the wires electrically interconnect the second bonding pads and at least some of the leads.

In accordance with the present invention, there is also provided a multi-chip stacked packaging structure, comprising at least one first chip stacked group comprising at least two chips including a first chip having a first active surface and a first back surface, the first active surface comprising a central area and a peripheral area having a plurality of first bonding pads, a second chip having a second active surface and a second back surface, the second active surface comprising a central area and a peripheral area having a plurality of second bonding pads, the second back surface adhered to the first active surface so as to leave exposed the first bonding pads; a lead frame, comprising a plurality of leads and a chip supporting pad having a first adhering surface and a second adhering surface, the first adhering surface adhered to the second active surface of the first chip to leave exposed the first and the second bonding pads; at least one second chip stacked group comprising at least two chips including a third chip having a third active surface and a third back surface, the third active surface comprising a central area and a peripheral area having a plurality of third bonding pads, a fourth chip having a fourth active surface and a fourth back surface, the fourth active surface comprising a central area and a peripheral area having a plurality of fourth bonding pads, the fourth back surface adhered to the third back surface so as to leave exposed the fourth bonding pads, the third active surface adhered to the second adhering surface of the lead frame so as to leave exposed the third and fourth bonding pads; and a plurality of wires, wherein parts of the wires electrically interconnect the first bonding pads and at least some of the leads, parts of the wires electrically interconnect the second bonding pads and at least some of the leads, parts of the wires electrically connect with the third bonding pads and at least some of the leads, and parts of the wires electrically interconnect the fourth bonding pads and at least some of the leads.

Additional features and advantages of the invention will be set forth in the description that follows, being apparent from the description or learned by practice of the invention. The objectives and other advantages of the invention will be realized and attained by the semiconductor device structures and methods of manufacture particularly pointed out in the written description and claims, as well as the appended drawings.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are incorporated in and constitute a part of this specification, illustrate embodiments of the invention and, together with the description, serve to explain the features, advantages, and principles of the invention.

In the drawings:

FIGS. 1 and 2 illustrate cross-sectional views of multi-chip stacked package structures consistent with embodiments of the present invention;

FIGS. 3A-3B illustrate plan views of multi-chip stacked package structures according to FIGS. 1 and 2 that are consistent with embodiments of the present invention;

FIGS. 3C-3D illustrate plan views of multi-chip stacked package structures according to FIGS. 1 and 2 that are consistent with embodiments of the present invention;

FIGS. 3E-3F illustrate plan views of multi-chip stacked package structures according to FIGS. 1 and 2 that are consistent with embodiments of the present invention;

FIGS. 4A-4D illustrate alternative multi-chip stacked package structures consistent with embodiments of the present invention;

FIGS. 5 and 6 illustrate cross-sectional views of multi-chip stacked package structures consistent with further embodiments of the present invention;

FIGS. 7A-7B illustrate plan views of multi-chip stacked package structures according to FIGS. 5 and 6 that are consistent with embodiments of the present invention; and

FIGS. 7C-7D illustrate plan views of multi-chip stacked package structures according to FIGS. 5 and 6 that are consistent with embodiments of the present invention.

### DESCRIPTION OF THE EMBODIMENTS

Reference will now be made in detail to embodiments of the present invention, examples of which are illustrated in the accompanying drawings. Wherever possible, the same or similar reference numbers will be used throughout the drawings to refer to the same or like parts.

Embodiments consistent with the present invention provide for a leadframe base thin package structure with two or more chips in the stacking structure. Package structures consistent with the present invention reduce stacking thickness by achieving stacking of two or more chips into the area of a thin small outline package (TSOP) structure. The present invention is applicable to increasing chip packing density and to integrating different functions in one package, such as in memory card technology, for example.

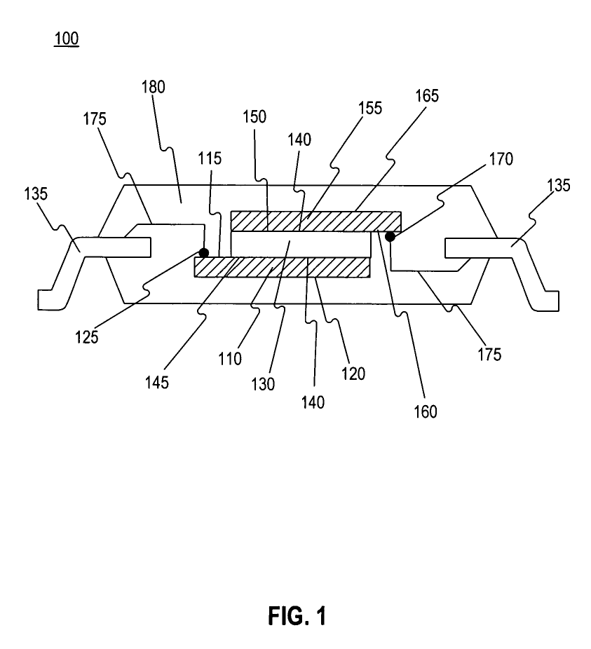

To solve problems associated with the approaches in the related art discussed above and consistent with an aspect of the present invention, package structures consistent with the present invention consistent will next be described with reference to FIGS. 1-6D.

FIG. 1 illustrates a cross-sectional view of a multi-chip stacked packaging structure 100 consistent with the present invention. The multi-chip stacked packaging structure 100 includes at least one first chip 110. First chip 110 has a first active surface 115 and a first back surface 120, first active surface 115 including a central area and a peripheral area having a plurality of first bonding pads 125. Multi-chip stacked packaging structure 100 also includes a lead frame 130. Lead frame 130 includes a plurality of leads 135 and a chip supporting pad 140 having at least a first adhering surface 145 and a second adhering surface 150, first adhering surface 145 adhered to first active surface 115 in such a way as to expose first bonding pads 125.

Still referring to FIG. 1, multi-chip stacked packaging structure 100 includes at least one second chip 155. Second chip 155 has a second active surface 160 and a second back surface 165, the second active surface comprising a central area and a peripheral area having a plurality of second bonding pads 170, second active surface 160 adhered to second adhering surface 150 of support pad 140 in such a way as to expose second bonding pads 170. Attached to first bonding pads 125 and second bonding pads 170 are a plurality of wires 175, wherein parts of wires 175 electrically interconnect first bonding pads 125 and at least some of the leads 135, and parts of wires 175 electrically interconnect second bonding pads 170 and at least some of leads 135.

Still referring to FIG. 1, first adhering surface 145 and first active surface 115, and second adhering surface 150 and second active surface 160, may be adhered by a nonconductive solid or liquid adhesive. In general, the adhesive may be a liquid, such as a non-conductive epoxy, or a solid, such as a non-conductive film. Surrounding multi-chip stacked packaging structure 100 may be an encapsulation 180 covering lead frame 130, first chip 110, second chip 155, and plurality of wires 175. Encapsulation 180 may be a plastic or resin material.

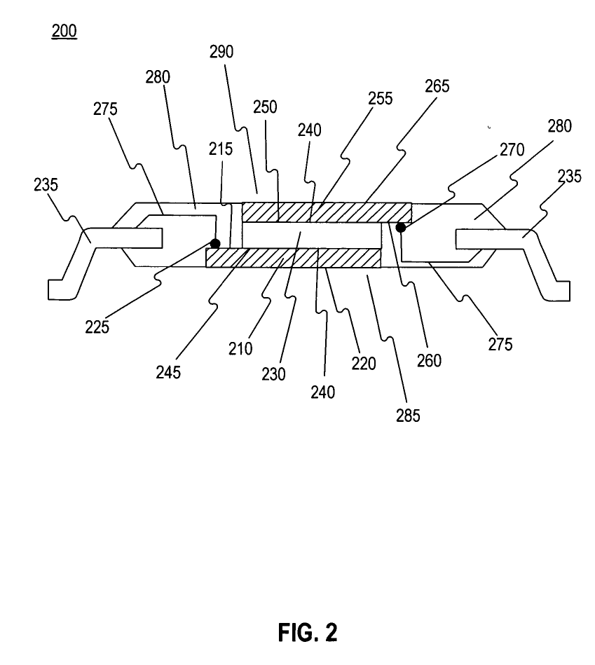

FIG. 2 illustrates a cross-sectional view of another multi-chip stacked packaging structure 200 consistent with the present invention. The multi-chip stacked packaging structure 200 includes at least one first chip 210. First chip 210 has a first active surface 215 and a first back surface 220, first active surface 215 including a central area and a peripheral area having a plurality of first bonding pads 225. Multi-chip stacked packaging structure 200 also includes a lead frame 230. Lead frame 230 includes a plurality of leads 235 and a chip supporting pad 240 having at least a first adhering surface 245 and a second adhering surface 250, first adhering surface 245 adhered to first active surface 215 in such a way as to expose first bonding pads 225.

Still referring to FIG. 2, multi-chip stacked packaging structure 200 includes at least one second chip 255. Second chip 255 has a second active surface 260 and a second back surface 265, the second active surface comprising a central area and a peripheral area having a plurality of second bonding pads 270, second active surface 260 adhered to second adhering surface 250 of supporting pad 240 in such a way as to expose second bonding pads 270. Attached to first bonding pads 225 and second bonding pads 270 are a plurality of wires 275, wherein parts of wires 275 electrically interconnect first bonding pads 225 and at least some of leads 235, and parts of the wires 275 electrically interconnect second bonding pads 270 and at least some of leads 235.

Still referring to FIG. 2, first adhering surface 245 and first active surface 215, and second adhering surface 250 and second active surface 260, may be adhered by a nonconductive solid or liquid adhesive. Surrounding multi-chip stacked packaging structure 200 may be an encapsulation 280 covering lead frame 230, part of first chip 210, part of second chip 255, plurality of wires 275, and leaving exposed at least a portion 285 of first back surface 220 and at least a portion 290 of second back surface 265.

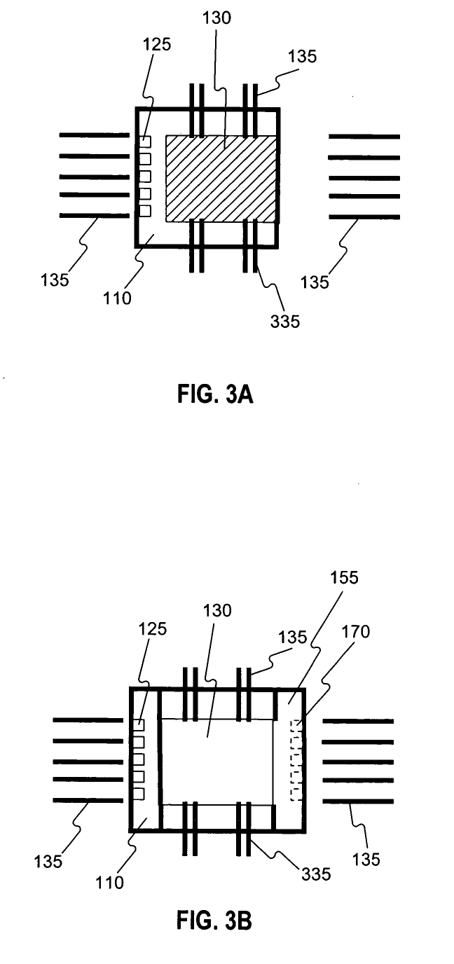

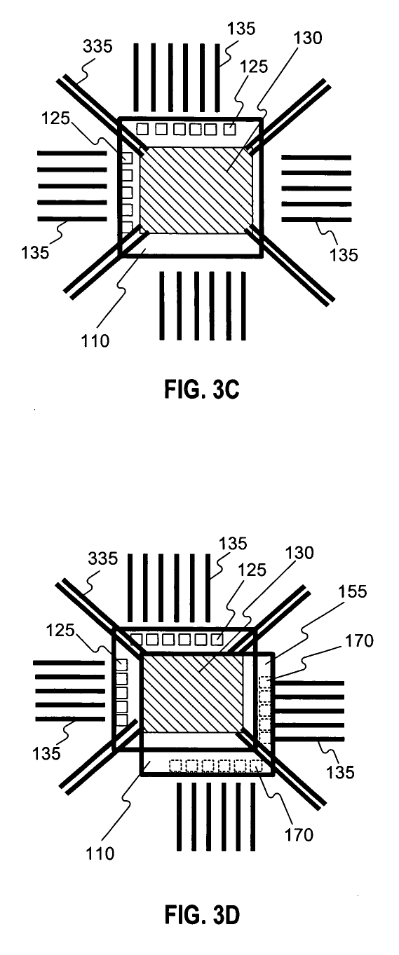

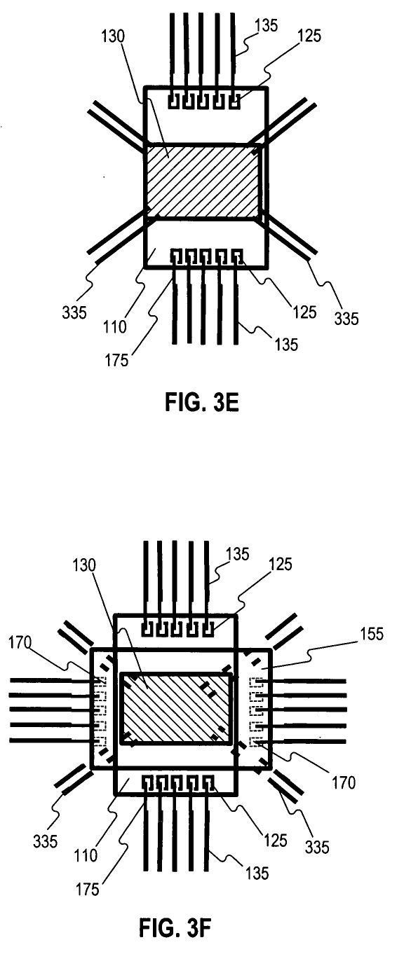

FIG. 3A illustrates a plan view of a part of multi-chip stacked packaging structure 100 shown in FIG. 1. Specifically, FIG. 3A illustrates first chip 110 underneath lead frame 130, surrounded by a plurality of leads 135, with second chip 155 removed. According to this embodiment, first bonding pads 125, shown to the left of lead frame 130, may be distributed only on one edge of the peripheral area of first chip 110. This configuration allows space for other leads 335 to access first chip 110 without interfering (mechanically or electrically) with first bonding pads 125. Similarly, second chip 155, shown in FIG. 3B, may have second bonding pads 170, shown to the right of the outline of lead frame 130 (beneath second chip 155 in FIG. 3B), also distributed only on one edge of the peripheral area of second chip 155. This configuration also allows space for other leads 335 to access second chip 155 without interfering (mechanically or electrically) with second bonding pads 170.

According to the embodiment described above, when second chip 155 is positioned over lead frame 130 and first chip 110 (as shown in FIG. 3B), the multi-chip stacked packaging structure 100 shown in FIG. 1 or the multi-chip stacked packaging structure 200 shown in FIG. 2 may be produced. As shown in FIG. 3B, two edges of second chip 155 are aligned with two edges of first chip 110. The resultant multi-chip stacked packaging structure has the advantages of reduced total thickness when compared to other structures in the art, and is compatible with standard leadframe and surface mount technology (SMT) processes.

FIG. 3C is a plan view of a part of multi-chip stacked packaging structure 100 shown in FIG. 1. Specifically, FIG. 3C illustrates first chip 110 underneath lead frame 130, surrounded by a plurality of leads 135, with second chip 155 removed. According to this embodiment, first bonding pads 125 may be distributed on two adjacent edges of the peripheral area of first chip 110. This configuration allows room for other leads 335 (shown at a diagonal in FIG. 3C in relation to first chip 110) to access first chip 110 without interfering (mechanically or electrically) with first bonding pads 125 on either of two adjacent edges of the peripheral area of first chip 110. Similarly, second chip 155, shown in FIG. 3D, may have second bonding pads 170 (shown beneath second chip 155 in FIG. 3D), on two adjacent edges of the peripheral area of second chip 155. This configuration also allows room for other leads 335 (shown at a diagonal in FIG. 3D in relation to second chip 155) to access second chip 155 without interfering (mechanically or electrically) with second bonding pads 170.

According to the embodiment described above, when second chip 155 is positioned over lead frame 130 and first chip 110 (as shown in FIG. 3D), multi-chip stacked packaging structure 100 shown in FIG. 1 or multi-chip stacked packaging structure 200 shown in FIG. 2 may be produced. As shown in FIG. 3D, the diagonals of first chip 110 and second chip 155 are aligned, such that second chip 155 is translated along the diagonal relative to first chip 110. The resultant multi-chip stacked packaging structure also has the advantages of reduced total thickness when compared to other structures in the art, and is compatible with standard leadframe and surface mount technology (SMT) processes.

Referring to FIG. 3E, a plan view of a part of multi-chip stacked packaging structure 100 shown in FIG. 1 is again illustrated. Specifically, FIG. 3D illustrates first chip 110 underneath lead frame 130, surrounded by a plurality of leads 135. According to this embodiment, first bonding pads 125 may be distributed on two opposite edges of the peripheral area of first chip 110. For illustrative purposes, wires 175 are shown in FIG. 3E connected to first bonding pads 125 and leads 135. This configuration allows room for other leads 335 (shown at a diagonal in FIG. 3E in relation to first chip 110) to access first chip 110 without interfering (mechanically or electrically) with first bonding pads 125 on either of two opposite edges of the peripheral area of first chip 110. Similarly, second chip 155, shown in FIG. 3F, may have second bonding pads 170 (shown beneath second chip 155 in FIG. 3F), on two opposite edges of the peripheral area of second chip 155. This configuration also allows room for other leads 335 (shown at a diagonal in FIG. 3F in relation to second chip 155) to access second chip 155 without interfering (mechanically or electrically) with second bonding pads 170.

According to the embodiment described above, when second chip 155 is positioned over lead frame 130 and first chip 110 (as shown in FIG. 3F), multi-chip stacked packaging structure 100 shown in FIG. 1 or multi-chip stacked packaging structure 200 shown in FIG. 2 may be produced. The resultant multi-chip stacked packaging structure also has the advantages of reduced total thickness when compared to other structures in the art, and is compatible with standard leadframe and surface mount technology (SMT) processes.

In any of the structures shown in FIGS. 3A-3F, the resultant multi-chip stacked packaging structure may be covered with an encapsulation 180 (shown in FIG. 1), or an encapsulation 280 (shown in FIG. 2) which leaves an exposed region 285 of the first back surface 120 and an exposed region 290 of the second back surface 165.

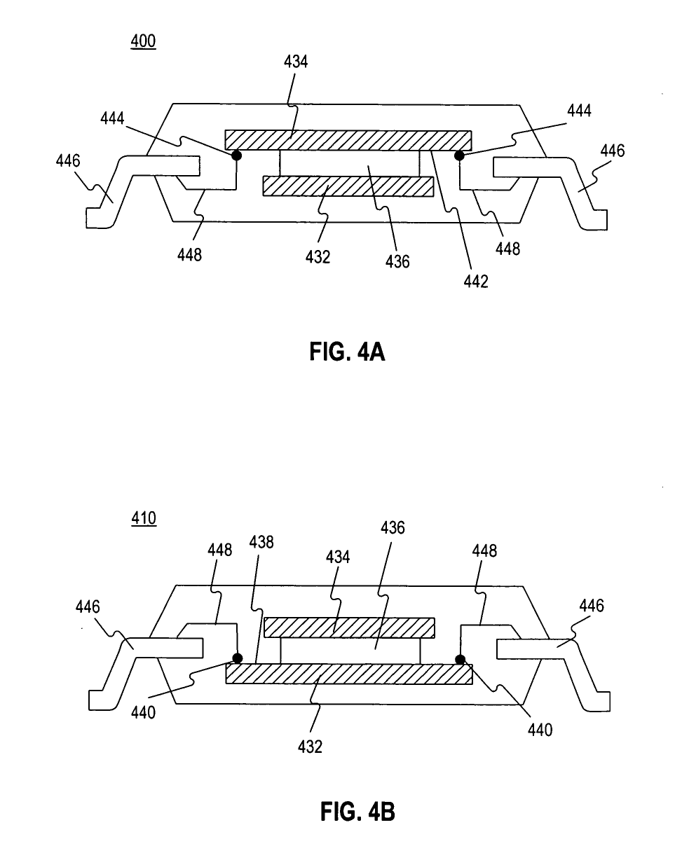

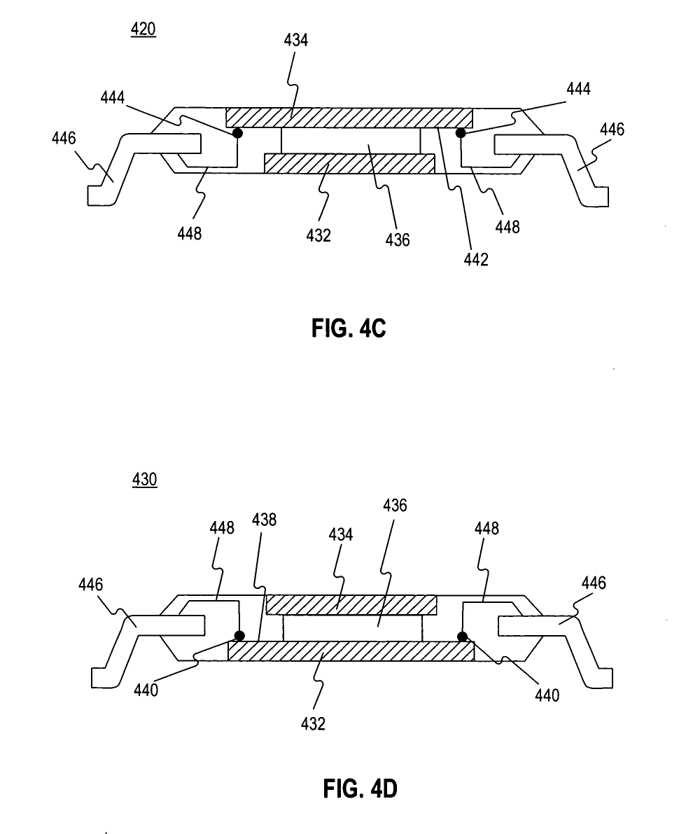

Other alternative encapsulation structures 400, 410, 420, and 430 consistent with the present invention are shown in FIGS. 4A-4D. These structures are similar to those shown in FIGS. 1 and 2, allowing for leads at opposite edges of either chip as shown in FIGS. 3E and 3F. Thus, each of structures 400, 410, 420, and 430 includes at least one first chip 432, at least one second chip 434, and a lead frame 436 disposed therebetween. In FIGS. 4B and 4D, first chip 432 has a first active surface 438 including a plurality of first bonding pads 440. In FIGS. 4A and 4C, second chip 434 has a second active surface 442 including a plurality of second bonding pads 444. Lead frame 436 includes a plurality of leads 446 connected to bonding pads 440, 444 by wires 448.

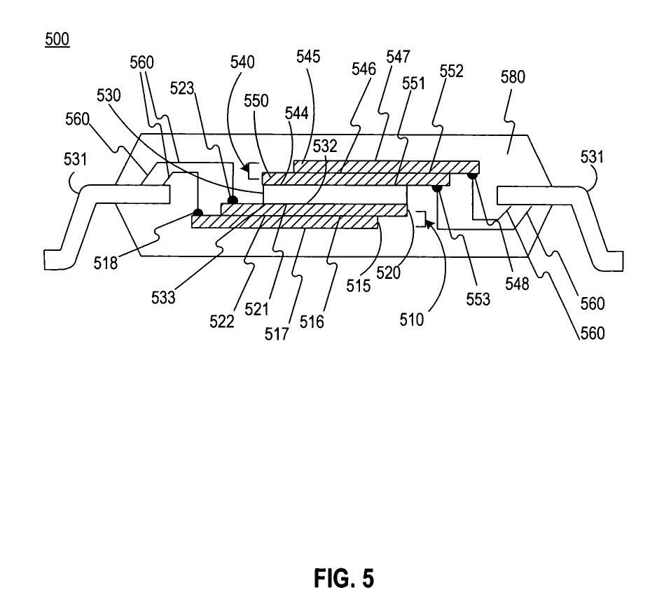

FIG. 5 illustrates a cross-sectional view of a multi-chip stacked packaging structure 500 consistent with the present invention. The multi-chip stacked packaging structure 500 includes at least one first chip stacked group 510 comprising at least two chips, the at least two chips including a first chip 515 having a first active surface 516 and a first back surface 517, the first active surface 516 comprising a central area and a peripheral area having a plurality of first bonding pads 518. First chip stacked group 510 also includes a second chip 520 having a second active surface 521 and a second back surface 522, second active surface 521 comprising a central area and a peripheral area having a plurality of second bonding pads 523. Consistent with this embodiment, second back surface 522 may be adhered to the first active surface 516 so as to leave exposed first bonding pads 518.

Still referring to FIG. 5, multi-chip stacked packaging structure 500 also includes a lead frame 530, comprising a plurality of leads 531 and a chip supporting pad 532 having a first adhering surface 533 and a second adhering surface 544, first adhering surface 533 adhered to second active surface 521 of second chip 520 in such a way as to leave exposed first and second bonding pads 518/523.

Multi-chip stacked packaging structure 500 further includes at least one second chip stacked group 540 comprising at least two chips, the at least two chips including a third chip 545 having a third active surface 546 and a third back surface 547, third active surface 546 comprising a central area and a peripheral area having a plurality of third bonding pads 548. Second chip stacked group 540 also includes is a fourth chip 550 having a fourth active surface 551 and a fourth back surface 552, fourth active surface 551 comprising a central area and a peripheral area having a plurality of fourth bonding pads 553. Consistent with this embodiment, fourth back surface 552 may be adhered to the third active surface 546 so as to leave exposed third bonding pads 548, and fourth active surface 551 may be adhered to second adhering surface 544 of chip supporting pad 532 so as to leave exposed third and fourth bonding pads 548/553.

Also shown in FIG. 5 are a plurality of wires 560, wherein parts of wires 560 electrically interconnect first bonding pads 518 and at least some of leads 531, parts of wires 560 electrically interconnect second bonding pads 523 and at least some of leads 531, parts of wires 560 electrically interconnect third bonding pads 548 and at least some of leads 531, and parts of wires 560 electrically connect fourth bonding pads 553 and at least some of leads 531.

Still referring to FIG. 5, first adhering surface 533 and first active surface 516, and second adhering surface 544 and second active surface 521, may be adhered by a nonconductive solid or liquid adhesive. Surrounding multi-chip stacked packaging structure 500 may be an encapsulation 580 covering lead frame 530, first chip stacked group 510, second chip stacked group 540, and plurality of wires 560.

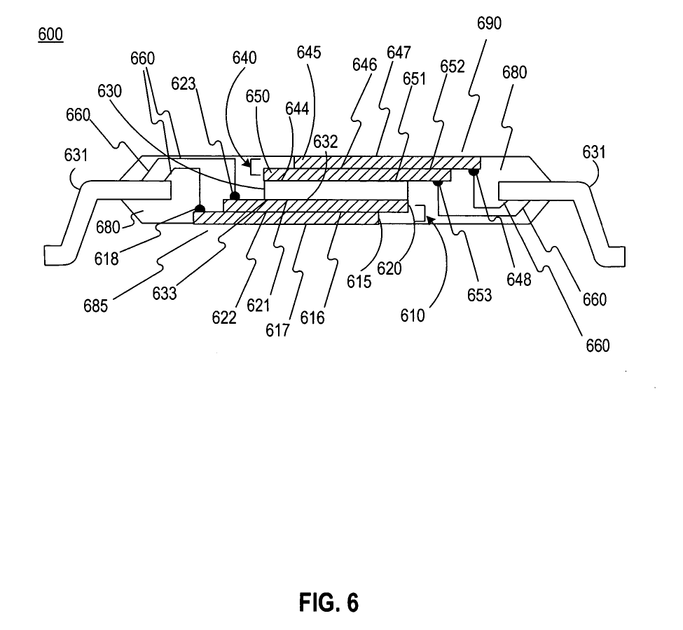

FIG. 6 is a cross-sectional view of another multi-chip stacked packaging structure 600 consistent with the present invention. Multi-chip stacked packaging structure 600 includes at least one first chip stacked group 610 comprising at least two chips, the at least two chips including a first chip 615 having a first active surface 616 and a first back surface 617, first active surface 616 comprising a central area and a peripheral area having a plurality of first bonding pads 618. Also included is a second chip 620 having a second active surface 621 and a second back surface 622, second active surface 621 comprising a central area and a peripheral area having a plurality of second bonding pads 623. Consistent with this embodiment, second back surface 622 may be adhered to the first active surface 616 so as to leave exposed first bonding pads 618.

Still referring to FIG. 6, multi-chip stacked packaging structure 600 also includes a lead frame 630, comprising a plurality of leads 631 and a chip supporting pad 632 having a first adhering surface 633 and a second adhering surface 644, first adhering surface 633 adhered to second active surface 621 of second chip 620 in such a way as to leave exposed first and second bonding pads 618/623.

Multi-chip stacked packaging structure 600 further includes at least one second chip stacked group 640 comprising at least two chips, the at least two chips including a third chip 645 having a third active surface 646 and a third back surface 647, third active surface 646 comprising a central area and a peripheral area having a plurality of third bonding pads 648. Also included is a fourth chip 650 having a fourth active surface 651 and a fourth back surface 652, fourth active surface 651 comprising a central area and a peripheral area having a plurality of fourth bonding pads 653. Consistent with this embodiment, fourth back surface 652 may be adhered to third active surface 646 so as to leave exposed third bonding pads 648, and fourth active surface 651 may be adhered to second adhering surface 644 of chip supporting pad 632 so as to leave exposed third and fourth bonding pads 648/653.

Also shown in FIG. 6 are a plurality of wires 660, wherein parts of the wires 660 electrically interconnect first bonding pads 618 and at least some of leads 631, parts of wires 660 electrically interconnect second bonding pads 623 and at least some of leads 631, parts of wires 660 electrically interconnect third bonding pads 648 and at least some of leads 631, and parts of wires 660 electrically interconnect fourth bonding pads 653 and at least some of leads 631.

Still referring to FIG. 6, first adhering surface 633 and first active surface 616, and second adhering surface 644 and second active surface 621, may be adhered by a nonconductive solid or liquid adhesive. Surrounding multi-chip stacked packaging structure 600 may be an encapsulation 680 covering the lead frame 630, part of first chip stacked group 610, part of second chip stacked group 640, and plurality of wires 660, but leave exposed at least a portion 685 of first back surface 617 and at least a portion 690 of third back surface 647.

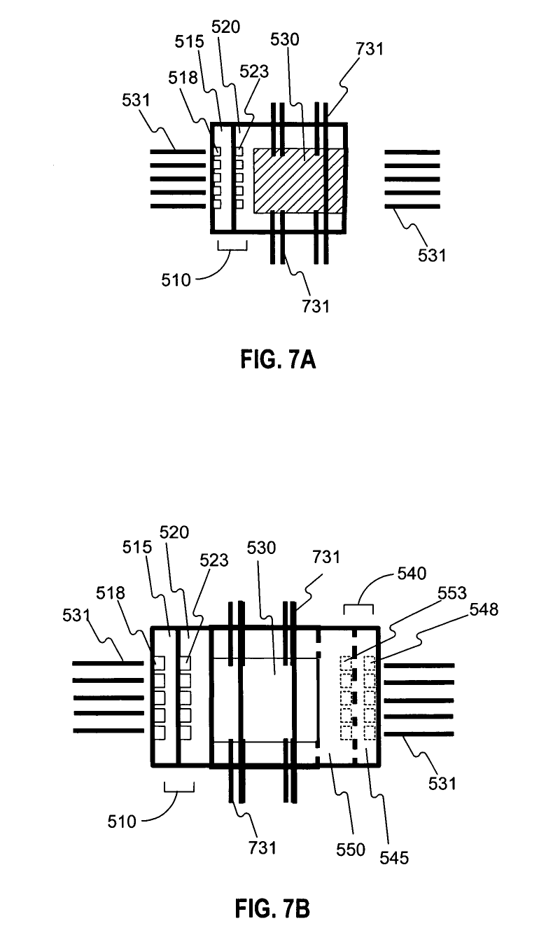

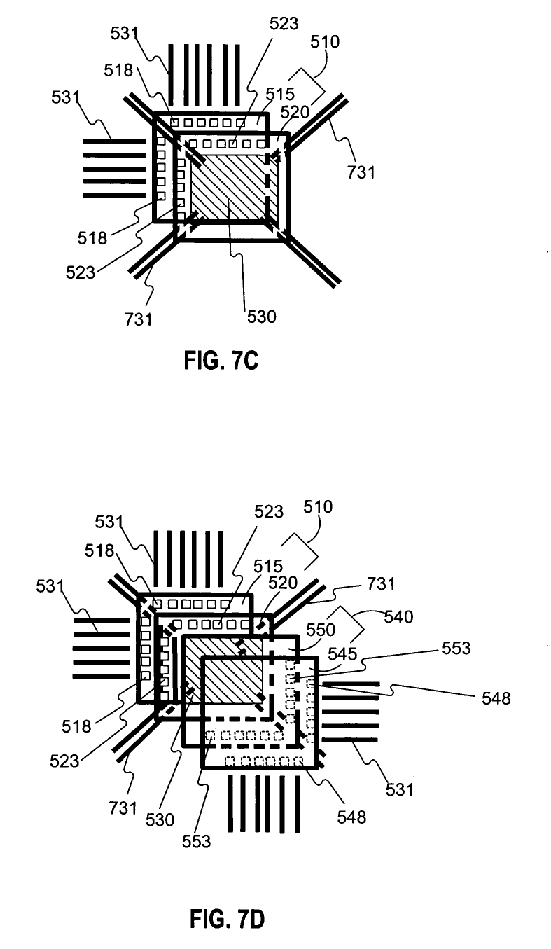

FIG. 7A illustrates a plan view of a part of the multi-chip stacked packaging structure 500 shown in FIG. 5. Specifically, FIG. 7A illustrates first chip stacked group 510 underneath lead frame 530, surrounded by a plurality of leads 531, with second chip stacked group 540 removed. According to this embodiment, first and second bonding pads 518/523, shown to the left of lead frame 530, may be distributed only on one edge of the peripheral area of each of first chip 515 and second chip 520. This configuration allows room for other leads 731 to access either or both of first chip 515 and second chip 520 without interfering (mechanically or electrically) with first and second bonding pads 518/523. Similarly, second chip stacked group 540, shown in FIG. 7B, may have third and fourth bonding pads 548/553, shown to the right of the outline of lead frame 530 (respectively beneath third chip 545 and fourth chip 550 in FIG. 7B), also distributed only on one edge of the peripheral area of each of third chip 545 and fourth chip 550. This configuration also allows room for other leads 731 to access any or all of first chip 515, second chip 520, third chip 545, and fourth chip 550, without interfering (mechanically or electrically) with third and fourth bonding pads 548/553.

According to the embodiment described above, when second chip stacked group 540 is positioned over lead frame 530 and first chip stacked group 510 (as shown in FIG. 7B), multi-chip stacked packaging structure 500 shown in FIG. 5 or the multi-chip stacked packaging structure 600 shown in FIG. 6 may be produced. As shown in FIG. 7B, two edges of second chip stacked group 540 are aligned with two edges of first chip stacked group 510. The resultant multi-chip stacked packaging structure also has the advantages of reduced total thickness when compared to other structures in the art, and is compatible with standard leadframe and surface mount technology (SMT) processes.

Referring to FIG. 7C, a plan view of a part of multi-chip stacked packaging structure 500 (shown in FIG. 5) is illustrated. Specifically, FIG. 7C illustrates first chip stacked group 510 underneath lead frame 530, surrounded by a plurality of leads 531, with second chip stacked group 540 removed. According to this embodiment, first and second bonding pads 518/523 may be distributed on two adjacent edges of the peripheral area of each of first chip 515 and second chip 520. This configuration allows space for other leads 731 (shown at a diagonal in FIG. 7C in relation to first chip stacked group 510) to access either or both of first chip 515 and second chip 520 without interfering (mechanically or electrically) with first and second bonding pads 518/523. Similarly, second chip stacked group 540, shown in FIG. 7D, may have third and fourth bonding pads 548/553 distributed on two adjacent edges of the peripheral area of each of third chip 545 and fourth chip 550. Likewise, this configuration also allows space for other leads 731 to access any or all of first chip 515, second chip 520, third chip 545, and fourth chip 550, without interfering (mechanically or electrically) with third and fourth bonding pads 548/553.

According to the embodiment described above, when second chip stacked group 540 is positioned over lead frame 530 and first chip stacked group 510 (as shown in FIG. 7D), multi-chip stacked packaging structure 500 shown in FIG. 5 or multi-chip stacked packaging structure 600 shown in FIG. 6 may be produced. As shown in FIG. 7D, the diagonals of first chip stacked group 510 and second chip stacked group 540 are aligned, such that second chip stacked group 540 is translated along the diagonal relative to first chip stacked group 510. The resultant multi-chip stacked packaging structure also has the advantages of reduced total thickness when compared to other structures in the art, and is compatible with standard leadframe and surface mount technology (SMT) processes.

In any of the structures shown in FIGS. 7A-7D, the resultant multi-chip stacked packaging structure may be covered with an encapsulation 580 (shown in FIG. 5), or an encapsulation 680 (shown in FIG. 6) which leaves an exposed region 685 of the first back surface 617 and an exposed region 690 of the third back surface 647.

While we have stacked two stacked groups each with two chips, the invention is not so limited. The groups each can include more than two chips, and it is not necessary to have the same number of chips above and below the lead frames.

It will be apparent to those skilled in the art that various modifications and variations can be made in the disclosed structures and methods without departing from the scope or spirit of the invention. Other embodiments of the invention will be apparent to those skilled in the art from consideration of the specification and practice of the invention disclosed herein. It is intended that the specification and examples be considered as exemplary only, with a true scope and spirit of the invention being indicated by the following claims.

1. A multi-chip stacked packaging structure, comprising:
at least one first chip, having a first active surface and a first back surface, the first active surface comprising a central area and a peripheral area having a plurality of first bonding pads;
a lead frame, comprising a plurality of leads and a chip supporting pad having at least a first adhering surface and a second adhering surface, the first adhering surface adhered to the first active surface to leave exposed the first bonding pads;
at least one second chip, having a second active surface and a second back surface, the second active surface comprising a central area and a peripheral area having a plurality of second bonding pads, the second active surface adhered to the second adhering surface of the lead frame to leave exposed the second bonding pads; and
a plurality of wires, wherein parts of the wires electrically interconnect the first bonding pads and at least some of the leads, and parts of the wires electrically interconnect the second bonding pads and at least some of the leads.

2. The structure according to claim 1, wherein the first adhering surface and the first active surface, and the second adhering surface and the second active surface, are adhered by a nonconductive solid or liquid adhesive.

3. The structure according to claim 1, wherein the first bonding pads are distributed only on one edge of the peripheral area of the at least one first chip.

4. The structure according to claim 1, wherein the second bonding pads are distributed only on one edge of the peripheral area of the at least one second chip.

5. The structure according to claim 1, wherein the first bonding pads are distributed on two adjacent edges of the peripheral area of the at least one first chip.

6. The structure according to claim 1, wherein the second bonding pads are distributed on two adjacent edges of the peripheral area of the at least one second chip.

7. The structure according to claim 1, wherein the first bonding pads are distributed on two opposite edges of the peripheral area of the at least one first chip.

8. The structure according to claim 1, wherein the second bonding pads are distributed on two opposite edges of the peripheral area of the at least one second chip.

9. The structure according to claim 1, further comprising an encapsulation covering the lead frame, the at least one first chip, the at least one second chip, and the plurality of wires.

10. The structure according to claim 1, further comprising an encapsulation covering the lead frame, part of the at least one first chip, part of the at least one second chip, the plurality of wires, and leaving exposed at least a portion of the first back surface and at least a portion of the second back surface.

11. A multi-chip stacked packaging structure, comprising:
at least one first chip stacked group comprising at least two chips including
a first chip having a first active surface and a first back surface, the first active surface comprising a central area and a peripheral area having a plurality of first bonding pads,
a second chip having a second active surface and a second back surface, the second active surface comprising a central area and a peripheral area having a plurality of second bonding pads,
the second back surface adhered to the first active surface so as to leave exposed the first bonding pads;
a lead frame, comprising a plurality of leads and a chip supporting pad having a first adhering surface and a second adhering surface, the first adhering surface adhered to the second active surface of the first chip to leave exposed the first and the second bonding pads;
at least one second chip stacked group comprising at least two chips including
a third chip having a third active surface and a third back surface, the third active surface comprising a central area and a peripheral area having a plurality of third bonding pads,
a fourth chip having a fourth active surface and a fourth back surface, the fourth active surface comprising a central area and a peripheral area having a plurality of fourth bonding pads,
the fourth back surface adhered to the third active surface so as to leave exposed the third bonding pads,
the fourth active surface adhered to the second adhering surface of the lead frame so as to leave exposed the third and fourth bonding pads; and
a plurality of wires, wherein parts of the wires electrically interconnect the first bonding pads and at least some of the leads, parts of the wires electrically interconnect the second bonding pads and at least some of the leads, parts of the wires electrically interconnect the third bonding pads and at least some of the leads, and parts of the wires electrically interconnect the fourth bonding pads and at least some of the leads.

12. The structure according to claim 11, wherein the first adhering surface and the second active surface, the second back surface and the first active surface, the second adhering surface and the fourth active surface, and the fourth back surface and the third active surface, are adhered by a nonconductive solid or liquid adhesive.

13. The structure according to claim 11, wherein the first bonding pads are distributed only on one edge of the peripheral area of the at least one first chip.

14. The structure according to claim 11, wherein the second bonding pads are distributed only on one edge of the peripheral area of the at least one second chip.

15. The structure according to claim 11, wherein the third bonding pads are distributed only on one edge of the peripheral area of the at least one third chip.

16. The structure according to claim 11, wherein the fourth bonding pads are distributed only on one edge of the peripheral area of the at least one fourth chip.

17. The structure according to claim 11, wherein the first bonding pads are distributed on two adjacent edges of the peripheral area of the at least one first chip.

18. The structure according to claim 11, wherein the second bonding pads are distributed on two adjacent edges of the peripheral area of the at least one second chip.

19. The structure according to claim 11, wherein the third bonding pads are distributed on two adjacent edges of the peripheral area of the at least one third chip.

20. The structure according to claim 11, wherein the fourth bonding pads are distributed on two adjacent edges of the peripheral area of the at least one fourth chip.

21. (canceled)

22. The structure according to claim 11, further comprising an encapsulation covering the lead frame, the at least one first chip stacked group, the at least one second chip stacked group, and the plurality of wires.

23. The structure according to claim 11, further comprising an encapsulation covering the lead frame, part of the at least one first chip stacked group, part of the at least one second chip stacked group, the plurality of wires, and leaving exposed at least a portion of the first back surface and at least a portion of the third back surface.
